(19) United States
(12) Patent Application Publication
(10) Pub. No.: US 2022/0416203 A1
(43) Pub. Date: Dec. 29, 2022

(54) ELECTRONIC DEVICE

(71) Applicant: ASUSTeK COMPUTER INC., Taipei City (TW)

(72) Inventors: Chin-An Tseng, Taipei City (TW); Kun-Chan Lee, Taipei City (TW); Yen-Hsun Chen, Taipei City (TW); Hong-Bin Liu, Taipei City (TW)

(73) Assignee: ASUSTeK COMPUTER INC., Taipei City (TW)

(21) Appl. No.: 17/834,952

(22) Filed: Jun. 8, 2022

(30) Foreign Application Priority Data
Jun. 23, 2021 (CN) 202110698689.X

(51) Int. Cl. H01L 51/52; H01L 27/32

(52) U.S. Cl. CPC H01L 51/5253; H01L 27/323

(57) ABSTRACT

The disclosure provides an electronic device, including a display panel, an infrared light source, and an infrared cutoff layer. The display panel includes a display surface, a back surface opposite to the display surface, and a side surface connecting the display surface and the back surface. The infrared light source is disposed adjacent to the side surface of the display panel and is configured to emit infrared light. The display panel includes an overlapping region in which the infrared light source overlaps with the side surface as viewed from a side view. The infrared cutoff layer is attached to the side surface and the back surface of the display panel, and covers at least the overlapping region and an extension region in which the overlapping region extends respectively in a transverse direction and toward the back surface by a preset distance.

### CROSS-REFERENCE TO RELATED APPLICATION

This application claims the priority benefit of Chinese application serial No. 202110698689.X, filed on Jun. 23, 2021. The entirety of the above-mentioned patent application is hereby incorporated by reference herein and made a part of the specification.

### BACKGROUND OF THE INVENTION

### Field of the Invention

The disclosure relates to an electronic device including an infrared light source.

### Description of the Related Art

An infrared ray is also referred to as infrared light and has properties such as reflection, refraction, scattering, interference, and absorption. Any substance with a specific temperature (higher than absolute zero) radiates infrared rays. An infrared ranging sensor detects distances of obstacles by using a principle that infrared signals have different reflection intensities when encountering the obstacles at different distances. With the rapid development of communication technologies, mobile phones have become indispensable carry-on articles in people's daily life. Infrared ranging technologies are combined with the mobile phone, to improve functions and diversity of the mobile phone.

However, an infrared light source is generally disposed adjacent to a display panel. Especially, in a case that the infrared light source is matched with an organic electroluminescence display panel, the organic electroluminescence display panel is easily affected by the infrared light source to cause water ripples to flicker at edges of the display panel.

### BRIEF SUMMARY OF THE INVENTION

According to an aspect, an electronic device is provided. The electronic device includes a display panel, an infrared light source, and an infrared cutoff layer. The display panel includes a display surface, a back surface opposite to the display surface, and a side surface connecting the display surface and the back surface. The infrared light source is disposed adjacent to the side surface of the display panel and is configured to emit infrared light. The display panel includes an overlapping region in which the infrared light source overlaps with the side surface as viewed from a side view. The infrared cutoff layer is attached to the side surface and the back surface of the display panel, and covers at least the overlapping region and an extension region in which the overlapping region extends respectively in a transverse direction and toward the back surface by a preset distance.

Based on the above, in the electronic device of the disclosure, an infrared cutoff layer is attached to a side surface and a back surface of a display panel, and is caused to cover at least a region in the display panel in which an infrared light source overlaps with the display panel (as viewed from a side view) and an extension region in which the overlapping region extends respectively in a transverse direction and toward the back surface by a preset distance. Therefore, the impact of infrared light emitted by the infrared light source on the display panel is prevented, thereby improving the display quality of the electronic device.

### BRIEF DESCRIPTION OF THE DRAWINGS

The accompanying drawings are included to provide further understanding of the invention, and are incorporated in and constitute a part of this specification. The accompanying drawings illustrate embodiments of the invention and explain the principles of the invention in combination with the description.

FIG. 1 is a schematic partial cross-sectional view of an electronic device according to an embodiment of the disclosure;

FIG. 2 is a schematic partial top view of the electronic device in FIG. 1;

FIG. 3 is a schematic partial cross-sectional view of an electronic device according to another embodiment of the disclosure;

FIG. 4 is a schematic partial cross-sectional view of an electronic device according to still another embodiment of the disclosure; and

FIG. 5 is a schematic partial top view of an electronic device according to the embodiment of FIG. 3.

### DETAILED DESCRIPTION OF THE EMBODIMENTS

References will be made in detail to exemplary embodiments of the invention, and examples of exemplary embodiments are described in the accompanying drawings. Whenever possible, the same element symbols are used in the accompanying drawings and descriptions to represent the same or similar parts.

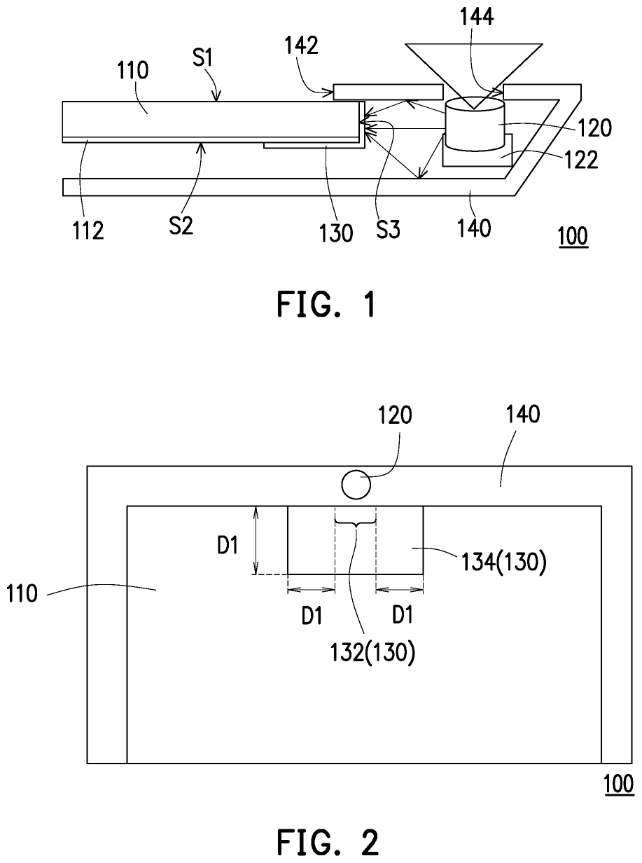

FIG. 1 is a schematic partial cross-sectional view of an electronic device according to an embodiment of the disclosure. FIG. 2 is a schematic partial top view of the electronic device in FIG. 1. Referring to FIG. 1 and FIG. 2 together, in an embodiment, an electronic device 100 includes a display panel 110, an infrared light source 120, and an infrared cutoff layer 130. The display panel 110 includes a display surface S1, a back surface S2, and a side surface S3. The back surface S2 is opposite to the display surface S1, and the side surface S3 is connected to the display surface S1 and the back surface S2 that are opposite to each other. In an embodiment, the electronic device 100 is a portable electronic device such as a smartphone, a tablet computer, or a notebook computer. Definitely, in other embodiments, the electronic device 100 is alternatively any device including a display and an infrared light source. In an embodiment, the display panel 110 is an organic electroluminescence display panel, which belongs to a current-type organic light-emitting device, and emits light by injecting and recombining carriers. In other embodiments, the display panel 110 is alternatively a display panel in another appropriate form.

In an embodiment, the infrared light source 120 is disposed adjacent to the side surface S3 of the display panel 110 and is configured to emit infrared light. In an embodiment, the infrared light source 120 is an infrared light-emitting diode. In some embodiments, the electronic device 100 includes an infrared sensor, and the infrared light source 120 is used as an infrared signal source of the infrared sensor. The infrared light emitted by the infrared light source 120 has properties such as reflection, refraction, scattering, interference, and absorption. Any substance with a specific temperature (higher than absolute zero) radiates infrared rays. Therefore, the infrared sensor detects distances of obstacles by using a principle that infrared signals have different reflection intensities when encountering the obstacles at different distances. In another embodiment, the electronic device 100 includes an infrared camera, and the infrared light source 120 is used as a main light source of the infrared camera. The infrared camera is a device that converts a temperature distribution image of a target object into a video image mainly by detecting infrared radiation of the target object and performing photoelectric conversion, signal processing, and the like. In this embodiment, a specific distance is maintained between the infrared light source 120 and the side surface S3 of the display panel 110, and a light-emitting direction of the infrared light source 120 is the same as a light-emitting direction of the display panel 110 (in an embodiment, the directions are both upward). In some embodiments, the infrared light source 120 is disposed on a circuit board 122 (in an embodiment, a printed circuit board).

As shown in FIG. 1 and FIG. 2, in an embodiment, the infrared cutoff layer 130 is attached to the side surface S3 and the back surface S2 of the display panel 110, to avoid a case that the infrared light emitted by the infrared light source 120 enters the display panel 110 in manners such as reflection, refraction, and scattering to affect the display quality of the display panel 110. The transmittance of the infrared cutoff layer 130 to the infrared light is slightly less than or equal to 15%. Further, the transmittance of the infrared cutoff layer 130 to the infrared light with a wavelength in a range of about 700 nanometers (nm) to about 1000 nm is slightly less than or equal to 15%. In some embodiments, the infrared cutoff layer 130 is a black adhesive tape. For an infrared ray, a black object has very high absorptivity, but very low reflectivity. Therefore, when the black adhesive tape is used as the infrared cutoff layer 130 and attached to the side surface S3 and the back surface S2 of the display panel 110, most of the infrared light emitted by the infrared light source 120 is absorbed. In addition, using the black adhesive tape as the infrared cutoff layer 130 further has advantages such as low costs, easy accessibility, and easy assembly. In other embodiments, the infrared cutoff layer 130 includes a black adhesive tape or an infrared cutoff filter. In this embodiment, the infrared cutoff layer 130 is an infrared cutoff filter which is a filter applied to filtering of an infrared wave band. Atypical infrared cutoff filter is generally a blue lens.

In an embodiment, the infrared cutoff layer 130 covers at least an overlapping region 132 and an extension region 134 of the display panel 110. When viewed from a side view, the overlapping region 132 is a region in which the infrared light source 120 overlaps with the side surface S3 of the display panel 110. The extension region 134 is a region in which the overlapping region 132 extends respectively in a transverse direction and toward the back surface by a preset distance D1. In an embodiment, the preset distance D1 is generally in a range of 5 millimeters (mm) to 15 mm. In an embodiment, the preset distance D1 is generally about 10 mm. Specifically, the infrared light source 120 overlaps with the side surface S3 of the display panel 110 as viewed from the side view. Therefore, the overlapping region 132 is located on the side surface S3 of the display panel 110 and corresponds to the infrared light source 120, and the extension region 134 is a region in which the overlapping region 132 respectively extends in the transverse direction (respectively leftward and rightward) and toward the back surface by the preset distance D1 of about 5 mm to 15 mm. In this case, such a configuration that the infrared cutoff layer 130 covers at least the overlapping region 132 and the extension region 134 of the display panel 110 effectively reduces the impact of the infrared light emitted by the infrared light source 120 on the display panel 110.

In some embodiments, as shown in FIG. 1, the display panel 110 further includes a metal foil layer 112 locating on the back surface S2 of the display panel 110, and the infrared cutoff layer 130 covers the metal foil layer 112. In an embodiment, the metal foil layer 112 includes a copper foil layer, an aluminum foil layer, or another appropriate metal foil layer, which is used for preventing static electricity to prevent electrostatic discharge (ESD) damage and is configured to reflect a part of the infrared light. Therefore, the metal foil layer 112 disposed on the back surface S2 of the display panel 110 is used to match the infrared cutoff layer 130, to further prevent the infrared light emitted by the infrared light source 120 from affecting the display panel 110. In addition, the electronic device 100 further includes a frame 140. In an embodiment, the frame 140 is a housing of the electronic device and includes a display opening 142 and a light source opening 144. The display opening 142 exposes and encloses the display surface S1 of the display panel 110, and the light source opening 144 exposes and encloses a light-emitting surface of the infrared light source 120. In an embodiment, the frame 140 reflects or absorbs the infrared light emitted by the infrared light source 120.

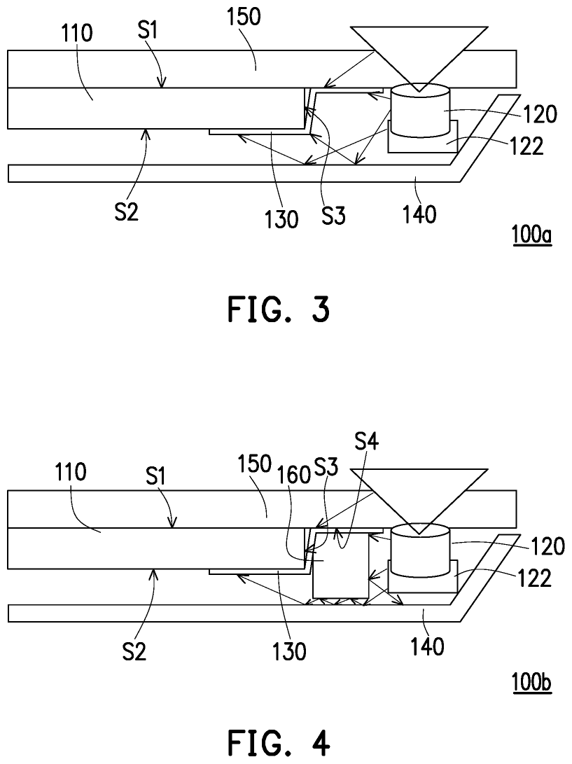

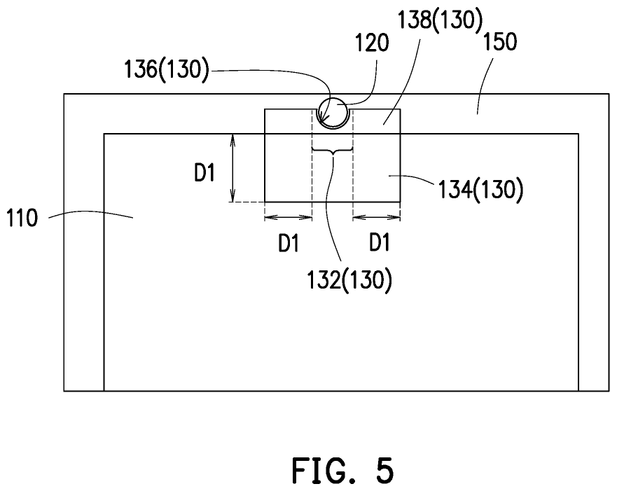

FIG. 3 is a schematic partial cross-sectional view of an electronic device according to another embodiment of the disclosure. FIG. 5 is a schematic partial top view of an electronic device according to the embodiment of FIG. 3. It is to be noted herein that an electronic device 100a of this embodiment is similar to the electronic device 100 in FIG. 1 and FIG. 2. Therefore, component numerals and a part of content of the foregoing embodiments continue to be used in this embodiment. Same or similar components are denoted by same numerals, and a description of the same technical content is omitted. Reference is made to the foregoing embodiments for the omitted description, and details are not repeated in this embodiment. The following mainly describes the difference between the electronic device 100a of this embodiment and the electronic device 100 in FIG. 1 and FIG. 2.

Referring to FIG. 3 and FIG. 5 together, in some embodiments, the electronic device 100a further includes a touch panel 150 disposed above the display panel 110 and the infrared light source 120. Specifically, the touch panel 150 further includes a piece of cover glass disposed on the display panel 110 and extending to a position above the infrared light source 120. In an embodiment, the touch panel 150 includes an opening corresponding to the infrared light source 120 to expose and enclose the light-emitting surface of the infrared light source 120. In such a configuration, the infrared cutoff layer 130 extends to be attached to a lower surface S4 of the touch panel 150, as shown in FIG. 3. Specifically, the lower surface S4 of the touch panel 150 covers a gap between the display panel 110 and the infrared light source 120, and the infrared cutoff layer 130 covers at least a part of the lower surface S4 located above the gap between the display panel 110 and the infrared light source 120, to further prevent the infrared light emitted by the infrared light source 120 from entering the touch panel 150 and being incident into the display panel 110 through the touch panel 150.

Referring to FIG. 5, in some embodiments, a width of a part of the infrared cutoff layer 130 that extends to the lower surface S4 of the touch panel 150 is the same as a width of a part of the infrared cutoff layer 130 that is attached to the display panel 110 (a width of the overlapping region 132 plus a width of the extension region 134). In some embodiments, in addition to covering a region above the gap between the display panel 110 and the infrared light source 120, the infrared cutoff layer 130 that extends to the lower surface S4 of the touch panel 150 further extends to an edge enclosing the infrared light source 120. As shown in FIG. 5, the infrared cutoff layer 130 includes a notch 136 corresponding to the infrared light source 120. The notch 136 surrounds at least a part of the infrared light source 120 (in an embodiment, surrounds half of the infrared light source 120). In other embodiments, the infrared cutoff layer 130 extends toward the infrared light source 120 and beyond a region in which the infrared light source 120 is disposed, and the notch of the infrared cutoff layer 130 completely surrounds the infrared light source 120. In some embodiments, the infrared cutoff layer 130 includes an alignment mark 138 to align with an attachment position of the infrared cutoff layer 130. In this embodiment, the alignment mark 138 of the infrared cutoff layer 130 is an alignment line which is designed to align with an interface between the display panel 110 and the touch panel 150.

FIG. 4 is a schematic partial cross-sectional view of an electronic device according to still another embodiment of the disclosure. It is to be noted herein that an electronic device 100b of this embodiment is similar to the electronic device 100a in FIG. 3. Therefore, component numerals and a part of content of the foregoing embodiments continue to be used in this embodiment. Same or similar components are denoted by same numerals, and a description of the same technical content is omitted. Reference is made to the foregoing embodiments for the omitted description, and details are not repeated in this embodiment. The following mainly describes the difference between the electronic device 100b of this embodiment and the electronic device 100a in FIG. 3.

In some embodiments, the electronic device 100b further includes a light blocking structure 160 disposed between the display panel 110 and the infrared light source 120. In this embodiment, the light blocking structure 160 is, in an embodiment, a retaining wall structure which blocks the transmission of the infrared rays, is located below the touch panel 150, and is disposed between the display panel 110 and the infrared light source 120. In an embodiment, there is a gap between an upper end of the light blocking structure 160 and the lower surface S4 of the touch panel 150. In some embodiments, a height of the light blocking structure 160 is slightly greater than a height of the infrared light source 120. In other words, the upper end of the light blocking structure 160 is slightly higher than an upper end of the infrared light source 120. In some embodiments, the material of the light blocking structure 160 includes an appropriate light blocking material such as foam, silica gel, or plastic. Definitely, the light blocking structure is alternatively made of various other materials as long as the materials have the effect of blocking the infrared light. In such a configuration, the infrared cutoff layer 130 extends along the lower surface S4 of the touch panel 150 to cover an upper portion of the light blocking structure 160. The light blocking structure 160 disposed between the display panel 110 and the infrared light source 120 is used to match the infrared cutoff layer 130, to further prevent the infrared light emitted by the infrared light source 120 from affecting the display panel 110. It is to be noted that, because the infrared cutoff layer 130 extends to cover the upper portion of the light blocking structure 160, a top view of the electronic device 100b is the same as or at least similar to the top view shown in FIG. 5.

To sum up, in the electronic device of the disclosure, an infrared cutoff layer is attached to a side surface and a back surface of a display panel, and is caused to cover at least a region in the display panel in which an infrared light source overlaps with the display panel (as viewed from a side view) and an extension region in which the overlapping region extends respectively in a transverse direction and toward the back surface by a preset distance. Therefore, the impact of infrared light emitted by the infrared light source on the display panel is prevented, thereby improving the display quality of the electronic device.

Finally, it is to be noted that the foregoing embodiments are merely used for describing technical solutions of the invention, but are not intended to limit the invention. Although the invention is described in detail with reference to the foregoing embodiments, a person of ordinary skill in the art is to understand that, modifications are still made to the technical solutions in the foregoing embodiments, or equivalent replacements are made to some or all of the technical features, and such modifications or replacements will not cause the essence of corresponding technical solutions to depart from the scope of the technical solutions in the embodiments of the invention.

What is claimed is:

1. An electronic device, comprising:
a display panel, comprising a display surface, a back surface opposite to the display surface, and a side surface connecting the display surface and the back surface;
an infrared light source, disposed adjacent to the side surface of the display panel, wherein the display panel comprises an overlapping region in which the infrared light source overlaps with the side surface as viewed from a side view; and
an infrared cutoff layer, attached to the side surface and the back surface of the display panel, and covering at least the overlapping region and an extension region in which the overlapping region extends respectively in a transverse direction and toward the back surface by a preset distance.

2. The electronic device according to claim 1, wherein the infrared cutoff layer comprises a black adhesive tape or an infrared cutoff filter.

3. The electronic device according to claim 1, wherein the transmittance of the infrared cutoff layer to infrared light is less than or equal to 15%.

4. The electronic device according to claim 1, wherein the preset distance is in a range of 5 millimeters (mm) to 15 mm.

5. The electronic device according to claim 1, wherein the display panel comprises an organic electroluminescence display panel.

6. The electronic device according to claim 1, further comprising a touch panel, disposed above the display panel and the infrared light source, wherein the infrared cutoff layer extends to be attached to a lower surface of the touch panel, and covers at least the lower surface located above a gap between the display panel and the infrared light source.

7. The electronic device according to claim 6, wherein the infrared cutoff layer comprises a notch corresponding to the infrared light source, and the notch surrounds at least a part of the infrared light source.

8. The electronic device according to claim 1, further comprising a light blocking structure, disposed between the display panel and the infrared light source.

9. The electronic device according to claim 1, further comprising a frame, comprising a display opening and a light source opening respectively exposing and enclosing the display panel and the infrared light source.

10. The electronic device according to claim 1, wherein the display panel further comprises a metal foil layer located on the back surface of the display panel, and the infrared cutoff layer covers the metal foil layer.
